(19) United States
(12) Patent Application Publication
(10) Pub. No.: US 2026/0344267 A1
(43) Pub. Date: Oct. 29, 2026

(54) DISPLAY APPARATUS

(71) Applicant: LG Display Co., Ltd., Seoul (KR)

(72) Inventors: Manki JI, Daegu (KR); Sungwoo LEE, Daegu (KR); Jinwoo PARK, Daegu (KR); Kyeongseob KWON, Muju-gun (KR)

(73) Assignee: LG Display Co., Ltd., Seoul (KR)

(21) Appl. No.: 19/640,323

(22) Filed: Apr. 6, 2026

(30) Foreign Application Priority Data
Apr. 28, 2025 (KR) 10-2025-0055762

(51) Int. Cl. H10K 59/80

(52) U.S. Cl. CPC H10K 59/879; H10K 59/873

(57) ABSTRACT

A display apparatus includes a display area disposed on a substrate, a non-display area disposed outside the display area, and a bezel area located in the non-display area. The bezel area includes a second area including a plurality of first structures, a first area disposed between the second area and the display area, and a third area disposed between the second area and an end of the substrate. An encapsulation portion is disposed on the plurality of first structures. A touch sensing unit is disposed on the encapsulation portion, and a lens is disposed on the touch sensing unit. A lens protection layer is disposed on the lens. A plurality of second structures is spaced apart from the lens in the non-display area, wherein at least one of the pluralities of second structures is disposed in the second area.

### CROSS-REFERENCE TO RELATED APPLICATION

This application claims priority from Republic of Korea Patent Application No. 10-2025-0055762 filed on Apr. 28, 2025, which is hereby incorporated by reference its entirety.

### BACKGROUND

### Technical Field

The present disclosure relates to a display apparatus. Without limitation, the present disclosure relates to a display apparatus that may be applied to a vehicle.

### Description of the Related Art

The contents described in this section merely provides background information on the present disclosure and does not constitute the prior art.

A display apparatus is applied to an electronic device in various fields. For example, the display apparatus may be used as a means for displaying information inside a vehicle. A display apparatus disposed inside the vehicle may provide information display or alarm display for a driver. In addition, the display apparatus may provide an image for a passenger. In addition, the display apparatus may include a function of providing information to a user and allowing the user to input information through a touch function.

As a proportion of the electronic devices in a vehicle increases, the number of types of the display apparatuses disposed inside the vehicle and an area size occupied with the display apparatuses in the vehicle are also increasing.

However, the information, image, or video displayed on a screen of the display apparatus may be of the type or content unrelated to the vehicle driving of the driver and thus may interfere with the driver when driving the vehicle.

### BRIEF SUMMARY

When an unnecessary screen among information or images provided from a display apparatus disposed inside a vehicle is displayed on a vehicle window in a frontward and/or upward direction of the driver’s seat, driving of the vehicle may be hindered. Accordingly, in order not to disturb the driver while driving the vehicle, a component for adjusting the viewing angle may be included in the display apparatus.

The component for adjusting the viewing angle may include a lens and a lens protection member for protecting the lens. The lens protection member may include a material having fluidity in order to realize a flat surface shape while protecting the lens disposed thereunder.

However, when the material having fluidity flows down to an outer area of the display apparatus, an overall height of the lens protection member may be reduced, and thus, it may be difficult for the lens protection member to protect the lens disposed thereunder.

Accordingly, the inventors of the present disclosure have invented a display apparatus capable of maintaining the overall height of the lens protection member to protect the lens through various experiments.

In addition, a technical purpose to be achieved according to embodiments of the present disclosure is to provide a display apparatus capable of preventing a material having fluidity for forming a lens protection member from flowing to an outer area of the display apparatus.

In addition, a technical purpose to be achieved according to embodiments of the present disclosure is to provide a display apparatus capable of maintaining thickness uniformity of a lens protection member in the display apparatus.

In addition, a technical purpose to be achieved according to embodiments of the present disclosure is to provide a display apparatus capable of preventing damage to metal lines positioned in an outer area of the display apparatus.

In addition, a technical purpose to be achieved according to embodiments of the present disclosure is to provide a display apparatus capable of reducing greenhouse gas emission by reducing production energy required for production of the display apparatus.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the present disclosure or combinations thereof.

A display apparatus according to one aspect of the present disclosure comprises: a display area disposed on a substrate and including a plurality of light-emitting elements; a non-display area disposed outside the display area; and a bezel area located in the non-display area and including a second area in which a plurality of first structures are disposed, a first area between the second area and the display area, and a third area between the second area and an end portion of the substrate, an encapsulation portion, at least a portion of the encapsulation portion disposed on the plurality of first structures; a lens disposed above the encapsulation portion; a lens protection layer disposed on the lens; and a plurality of second structures disposed to be spaced apart from the lens, wherein at least one of the plurality of second structures is disposed in the second area of the bezel area in which the plurality of first structures are disposed.

A display apparatus according to another aspect of the present disclosure comprises: a substrate including a display area and a non-display area outside the display area; a plurality of encapsulation dams disposed in the non-display area; an encapsulation portion, at least a portion of the encapsulation portion disposed on the plurality of encapsulation dams; a touch sensing unit disposed on the encapsulation portion and including a touch sensor and a touch insulating layer; a lens disposed on the touch sensing unit; a lens protection layer disposed on the lens; and a plurality of lens dams disposed in the non-display area to be spaced apart from the lens, wherein one of the plurality of lens dams overlaps one of the encapsulation dams in a vertical direction.

A display apparatus according to another aspect of the present disclosure comprises:
a display area disposed on a substrate and including a plurality of light-emitting elements; a non-display area disposed outside the display area; and a bezel area, the bezel area being located in the non-display area and including a first area adjacent to the display area, and a second area and a third area located farther from the display area than the first area; an encapsulation portion disposed in the first area and the second area; a lens disposed above the encapsulation portion; a lens protection member disposed on the lens; an insulating material flow control member disposed at the same height as the lens and spaced apart from the lens; and at least a portion of the lens protection member being located between the lens and the insulating material flow control member without extending beyond the insulating material flow control member.

In the display apparatus according to an embodiment of the present disclosure, at least a portion of the lens dam overlaps at least a portion of the encapsulation dam in the vertical direction such that the height of the lens dam may be maintained. Accordingly, the flow of the insulating material having fluidity may be controlled to prevent the insulating material from flowing to the outer area of the display apparatus. As a result, the thickness uniformity of the lens protection member may be secured to reliably protect the lens.

In addition, in the display apparatus according to an embodiment of the present disclosure, an extension pattern is included in at least one of the lens dams, thereby preventing the metal portion of the touch sensor disposed in the bezel area from being exposed to external impact or moisture penetration. This may prevent a touch operation defect from occurring due to damage to the metal portion of the touch sensor, thereby improving product reliability.

The display apparatus according to an embodiment of the present disclosure includes a component for adjusting a viewing angle, thereby preventing an image or a video that interferes with the driver from reflecting on a front window when the driver is driving the vehicle.

In addition, according to an embodiment of the present disclosure, the lens dam may be formed in the same process as the process for forming the component for adjusting the viewing angle, such that the number of the process steps may be reduced. Accordingly, there is an effect that production energy required for production of the display apparatus may be reduced and greenhouse gas emission may be reduced.

The effects of the present disclosure are not limited to the effects as mentioned above, and other effects not mentioned will be clearly understood by those skilled in the art from the following descriptions. Additional features and aspects will be set forth gradually in the description that follows, and will become apparent from the description, especially from embodiments, or may be learned by practice of the inventive concepts provided herein. Other features and aspects of the inventive concepts may be realized and attained by the structure particularly pointed out in the written description as well as the appended drawings.

### BRIEF DESCRIPTION OF THE SEVERAL VIEWS OF THE DRAWINGS

FIG. 1 illustrates an example in which a display apparatus according to an embodiment of the present disclosure is applied to a vehicle.

FIG. 2 is a plan view of a display apparatus according to embodiments of the present disclosure.

FIG. 3 is an enlarged view of an area I of FIG. 2.

FIG. 4 is a cross-sectional view taken along a line II-II′ of FIG. 3.

FIGS. 5 and 6 are diagrams illustrating examples of a lens.

FIGS. 7 and 8 are diagrams illustrating a display panel disposed inside a vehicle.

FIGS. 9-11 are diagrams illustrating a display apparatus according to an embodiment of the present disclosure.

FIGS. 12 and 13 are diagrams illustrating a display apparatus according to another embodiment of the present disclosure.

FIG. 14 is a diagram illustrating a display apparatus according to still another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers.

It will be understood that when an element or layer is referred to as being “connected to”, or “connected with” another element or layer, it may be directly on, connected to, or connected with the other element or layer, or one or more intervening elements or layers may be present.

In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on top” of another layer, film, region, plate, or the like, the former may directly contact the latter or still another layer, film, region, plate, or the like may be disposed between the former and the latter. As used herein, when a layer, film, region, plate, or the like is directly disposed “on” or “on top” of another layer, film, region, plate, or the like, the former directly contacts the latter and still another layer, film, region, plate, or the like is not disposed between the former and the latter. Further, as used herein, when a layer, film, region, plate, or the like is disposed “under” another layer, film, region, plate, or the like, the former may directly contact the latter or still another layer, film, region, plate, or the like may be disposed between the former and the latter. As used herein, when a layer, film, region, plate, or the like is directly disposed “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship with each other.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In description of flow of a signal, for example, when a signal is delivered from a node A to a node B, this may include a case where the signal is transferred from the node A to the node B via another node unless a phrase ‘immediately transferred’ or ‘directly transferred’ is used.

The present disclosure relates to a display apparatus, particularly suitable for vehicle applications, that includes a micro-lens structure for controlling viewing angles and a lens protection layer formed from a flowable insulating material. To address problems associated with the flow of this material toward the edge of the display panel—such as reduced thickness of the protection layer and inadequate protection of edge lenses—the apparatus incorporates one or more lens dams positioned in the bezel (non-display) area. These lens dams act as flow-control structures that limit outward spreading of the insulating material, thereby maintaining uniform thickness of the lens protection layer and ensuring reliable protection of the underlying micro-lenses.

In certain embodiments, at least one lens dam is disposed in a region containing encapsulation dams and overlaps one encapsulation dam in the vertical direction. This stacked configuration enhances the structural height and effectiveness of the barrier against the flowing material. Multiple lens dams may be arranged outwardly from the display area (e.g., first, second, and third lens dams), optionally with different heights or stepped configurations to sequentially control material flow and improve adhesion of an overlying polarizing layer. In some implementations, the outermost lens dam includes an extension pattern that covers an edge region of a touch insulating layer or associated metal lines to protect touch sensor electrodes from moisture ingress or mechanical damage.

The lens dams may be formed using the same material and fabrication process as the micro-lenses themselves, enabling integration without additional process steps. This reduces manufacturing complexity, production energy consumption, and associated greenhouse gas emissions. Through this combination of flow-control structures, vertical alignment with encapsulation dams, and process integration with lens formation, the display apparatus achieves improved thickness uniformity of the lens protection layer, enhanced durability of edge structures, and reliable operation of viewing-angle-controlled displays in applications such as vehicle interiors.

Hereinafter, a display apparatus according to each embodiment of the present disclosure will be described with reference to the accompanying drawings.

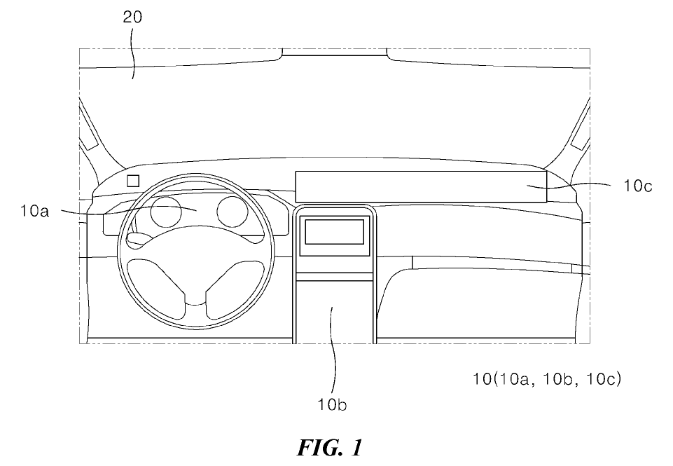

FIG. 1 illustrates an example in which a display apparatus according to an embodiment of the present disclosure is applied to a vehicle.

Referring to FIG. 1, a display apparatus including a display panel 10 according to embodiments of the present disclosure may be disposed inside a vehicle. For example, the display panel 10 may include a first display area 10a, a second display area 10b, and a third display area 10c. In an example, the first display area 10a may be disposed in front of the driver’s seat, the third display area 10c may be disposed in front of the passenger seat, and the second display area 10b may be disposed in a common space between the driver’s seat and the passenger seat.

The first display area 10a may provide information on the instrument panel indicating the driving state to the user of the driver’s seat. The second display area 10b or the third display area 10c may display navigation or video according to a user’s selection or a driving state of the vehicle. In an example, when the vehicle is running, the viewing angle of the second display area 10b or the third display area 10c may be controlled so as not to interfere with the driver’s driving. For example, the viewing angle may be controlled so that an image provided from the second display area 10b or the third display area 10c is not reflected on the glass window in the frontward and/or upward direction of the driver’s seat. In other words, the light emission direction of one or more of the first display area 10a, the second display area 10b, and the third display area 10c may be controlled as needed, such that an image or information is projected in a desired direction and is not emitted in an undesired direction.

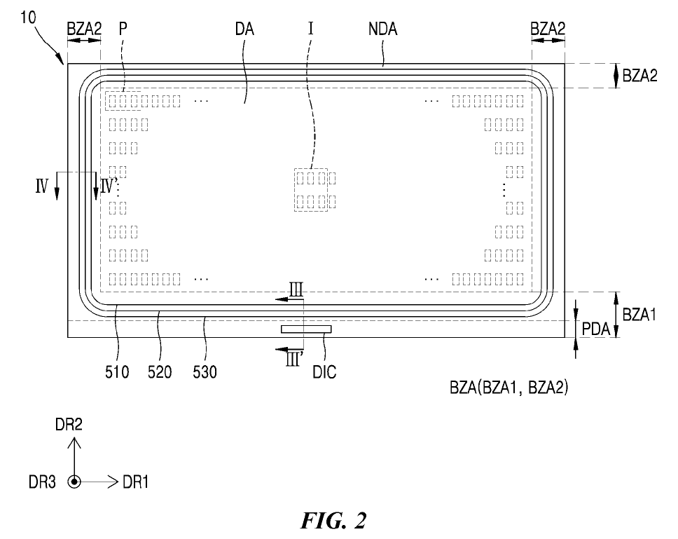

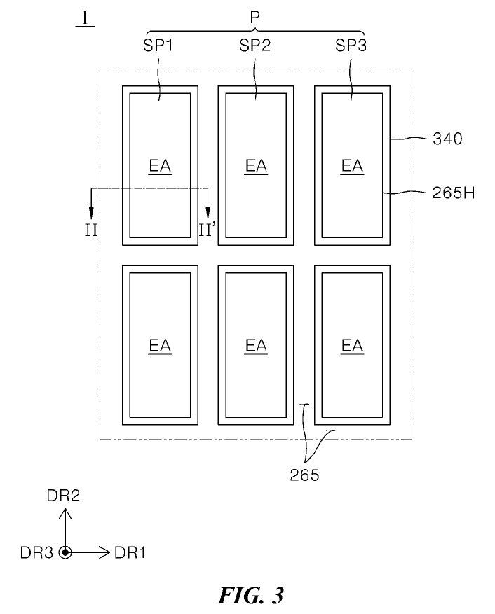

FIG. 2 is a plan view of a display apparatus according to embodiments of the present disclosure. Non-limitingly, the display apparatus shown in FIG. 2 may be one or more of the display apparatus illustrated in FIG. 1. FIG. 3 is an enlarged view of an area I of FIG. 2. FIG. 3 illustrates only a bank 265, a bank hole 265H, and a lens 340 for convenience of illustration.

Referring to FIGS. 2 and 3, the display apparatus according to an embodiment of the present disclosure may include a display panel 10 including a display area DA and a non-display area NDA positioned outside the display area DA.

The display panel 10 may include the display area DA and the non-display area NDA. The display area DA may be an area in which an image is displayed. The non-display area NDA may be an area in which no image is displayed. The non-display area NDA may be positioned in the peripheral area (or edge area) of the display panel 10. However, embodiments of the present disclosure are not limited thereto. For example, a remaining area except for a light emitting area in which light is emitted to the outside in the display area DA may be referred to as the non-display area NDA. A bezel area BZA of the display apparatus may be defined by the non-display area NDA. The bezel area BZA may surround the outside of the display area DA. The bezel area BZA may include a first bezel area BZA1 and a second bezel area BZA2. The first bezel area BZA1 may be positioned at a lower side the display panel 10, and the second bezel area BZA 2 may be positioned at upper side, left side, and right side of the display panel 10, and both opposing sides in the second direction DR2 intersecting the first direction DR1 of the display panel 10. The lower side of the display panel 10 in which the first bezel area BZA1 is positioned may be an area in which a pad area PDA in which a plurality of pads electrically connected to a printed circuit board or a driving circuit chip DIC are disposed is disposed.

A plurality of pixels P may be disposed in the display area DA. Each of the plurality of pixels P may include a plurality of sub-pixels SP1, SP2, and SP3. An image may be displayed through the plurality of sub-pixels SP1, SP2, and SP3 in the display area DA. The plurality of sub-pixels SP1, SP2, and SP3 may be arranged in an array in the display area DA. In an example, the plurality of sub-pixels SP1, SP2, and SP3 may be spaced apart from each other in the first direction DR1 and the second direction DR2 intersecting the first direction DR1 of the display area DA to form a matrix arrangement. The first direction DR1 may be a horizontal direction, an X-axis direction, or a row direction, the second direction DR2 may be a vertical direction, a Y-axis direction, or a column direction, and the third direction DR3 may be a direction perpendicular to both of the first direction DR1 and the second direction DR2. Referring to the example shown in FIG. 2, the third direction DR3 may be a direction inward into or outward from the plane view, and may also be a direction perpendicular to the screen display plane. However, embodiment of the present disclosure are not limited thereto, and the arrangement shape, arrangement order, and arrangement direction of the sub-pixels SP1, SP2, and SP3 may be variously changed.

In the present disclosure, one pixel P is configured to include the first sub-pixel SP1, the second sub-pixel SP2, and the third sub-pixel SP3. However, embodiment of the present disclosure are not limited thereto. For example, one pixel P may further include an additional sub-pixel.

The sub-pixels SP1, SP2, and SP3 may be implemented to emit light of the same color, such as white light, or may be implemented to respectively emit light of different colors, such as red, green, and blue colors. For example, the first sub-pixel SP1 may emit the red light, the second sub-pixel SP2 may emit the green light, and the third sub-pixel SP3 may emit the blue light.

Various lines and circuits for driving the plurality of subpixels SP1, SP2, and SP3 of the display area DA may be disposed in the non-display area NDA. For example, driving circuits including a gate driving circuit and a data driving circuit may be disposed in the non-display area NDA. Several drivers for driving the display area DA may be disposed in the non-display area NDA. For example, the driver may include a gate driver and a data driver. However, embodiments of the present disclosure are not limited thereto. A pad area PDA may be included in one edge of the non-display area NDA.

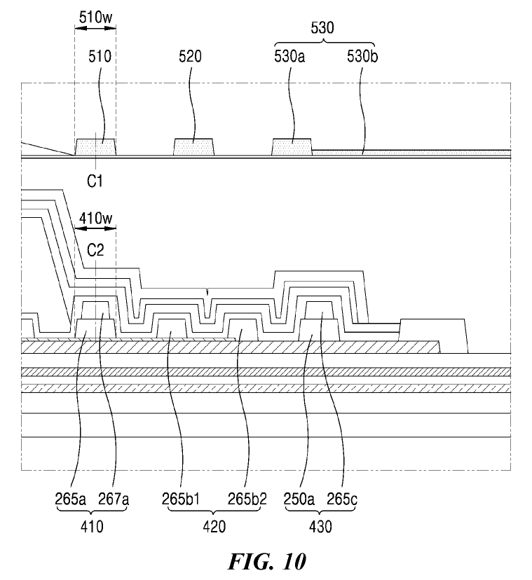

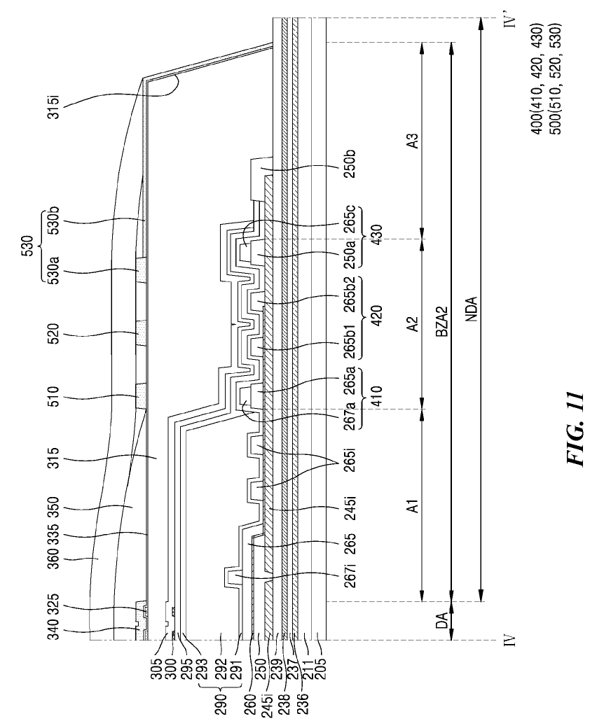

A plurality of lens dams 510, 520, and 530 may be disposed in the non-display area NDA so as to be spaced apart from each other. The plurality of lens dams 510, 520, and 530 may include a first lens dam 510, a second lens dam 520, and a third lens dam 530. Each of the lens dams 510, 520, and 530 may extend along the shape of the display area DA so as to surround the outside of the display area DA. Each of the lens dams 510, 520, and 530 may have a continuous line shape. For example, each of the lens dams 510, 520, and 530 may have a closed-loop line shape. In FIG. 2, for convenience of description, each of the lens dams 510, 520, and 530 is illustrated by a closed solid line. In a more microstructure, each of the lens dams 510, 520, and 530 may have a certain width. This will be described later with reference to FIGS. 9 and 10.

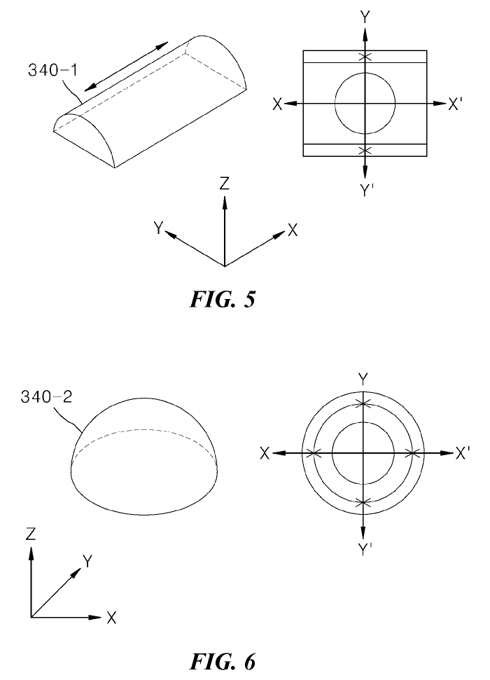

Referring to FIG. 3, the sub-pixels SP1, SP2, and SP3 may be distinguished from each other by a bank 265. For example, the bank hole 265H as an open area of the bank 265 may constitute a boundary area between neighboring sub-pixels and may define the light-emitting area EA. An area not covered with the bank 265 in each of the sub-pixels SP1, SP2, and SP3 may be the light-emitting area EA. The lens 340 as the viewing angle adjusting member may be disposed in each of the sub-pixels SP1, SP2, and SP3 and may overlap the light-emitting area EA. The lens 340 may include a hemispherical lens. However, embodiments of the present disclosure are not limited thereto. For example, the lens 340 may include a cylindrical lens. For example, the lens structures for adjusting a screen viewing angle may further include a micro lens array (MLA), a prism film/wedge lens, a freeform lens, and an electrically controllable liquid crystal lens, etc., which may realize a wide viewing angle, a narrow viewing angle, or output image light along a specific direction by changing a light exit direction, a diffusion angle, or left-eye/right-eye light splitting, etc. In an example, the lens 340 may function to prevent an unnecessary screen or image from being visible to the user. The lens 340 referred to as a component for adjusting a viewing angle. This will be described later with reference to FIGS. 5 and 6.

Hereinafter, an embodiment of one sub-pixel will be described.

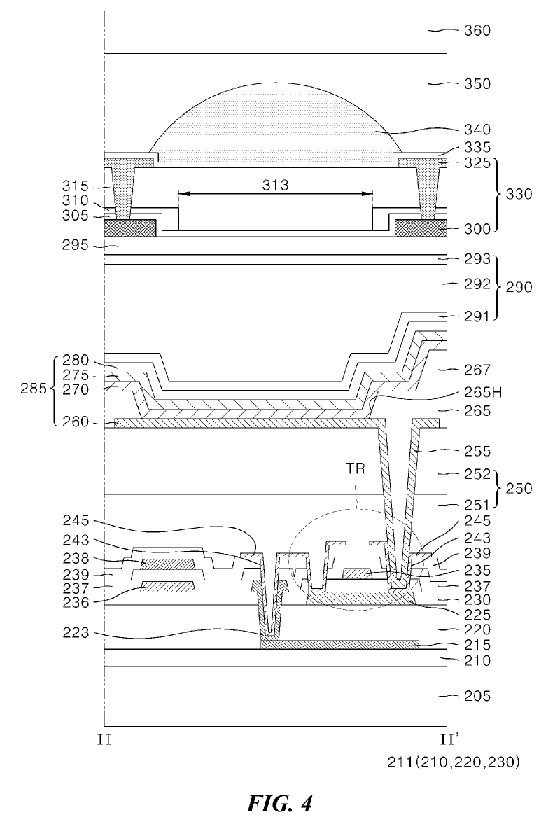

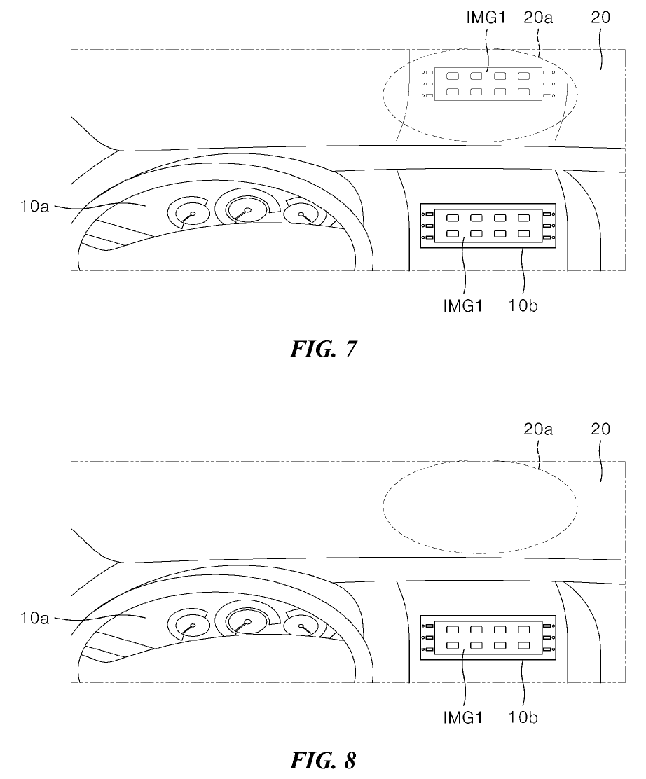

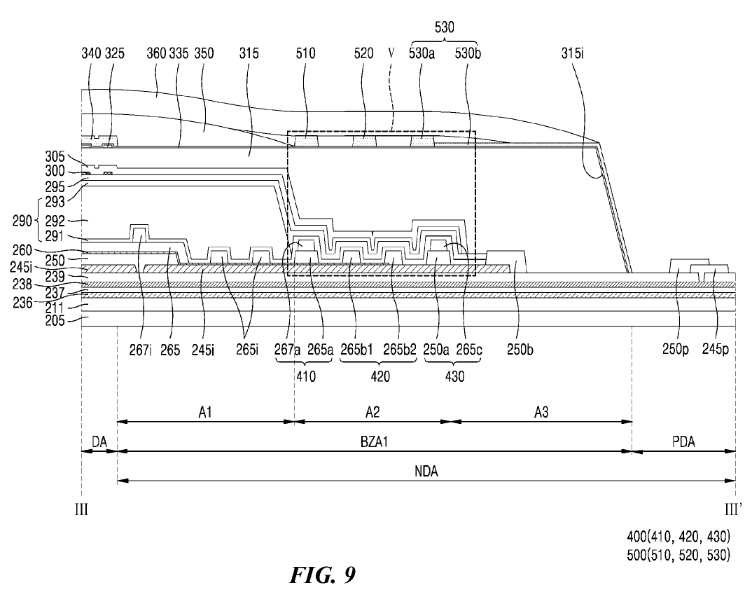

FIG. 4 is a cross-sectional view taken along a line II-II′ of FIG. 3. FIGS. 5 and 6 are diagrams illustrating the lens. FIGS. 7 and 8 are diagrams illustrating a display panel disposed inside a vehicle.

Referring to FIG. 4, the display panel 10 (see FIG. 2) may include a substrate 205, a pixel driving circuit including a transistor TR, a light-emitting element 285, a touch sensing unit (including touch sensor 330), the lens 340, a lens protection layer 350, and a polarizing layer 360.

One sub-pixel may include the light-emitting element 285 and a pixel driving circuit for applying a driving current to the light-emitting element 285. The pixel driving circuit may be disposed on the substrate 205, and the light-emitting element 285 may be disposed on the pixel driving circuit. The pixel driving circuit may include a driving transistor, one or more switching transistors, and a capacitor. In an example, the transistor TR may be a driving transistor. However, embodiments of the present disclosure are not limited thereto.

The substrate 205 may include a glass or flexible plastic film. When the substrate 205 is a plastic film, the substrate 205 may include multiple layers made of insulating materials. A first buffer layer 210 may be disposed on the substrate 205. The first buffer layer 210 may cover a surface of the substrate 205. For example, the first buffer layer 210 may entirely cover the surface of the substrate 205. The first buffer layer 210 may reduce or prevent penetration of moisture, oxygen, or impurities through the substrate 205. The first buffer layer 210 may be embodied as a single layer or a multilayer made of an inorganic insulating material such as silicon oxide (SiOx) or silicon nitride (SiNx).

A light shielding layer 215 may be disposed on the first buffer layer 210. The light shielding layer 215 may prevent external light from being incident on the transistor TR. To this end, an opaque metal material may be included in the light shielding layer 215. A second buffer layer 220 may be disposed on the light shielding layer 215. The second buffer layer 220 may be disposed across the entire surface of the substrate 205. The second buffer layer 220 may protect the transistor TR from moisture, oxygen, or impurities. The second buffer layer 220 may be embodied as a single layer or a multilayer made of an inorganic insulating material such as silicon oxide (SiOx) or silicon nitride (SiNx). However, embodiments of the present disclosure are not limited thereto.

The transistor TR may be disposed on the second buffer layer 220. The transistor TR may include a semiconductor layer 225, a gate electrode 235, and source/drain electrodes 245. The semiconductor layer 225 may include a channel area and a source/drain area. The area of the semiconductor layer 225 disposed to overlap the gate electrode 235 in the vertical direction may be a channel area. The source/drain areas may be disposed on both opposing sides of the channel area, respectively. The semiconductor layer 225 may be embodied as one of an oxide semiconductor layer, a polysilicon semiconductor layer, and a low-temperature polysilicon semiconductor layer, or a combination thereof. The semiconductor layer 225 may be disposed to overlap the light shielding layer 215 in the vertical direction. The light shielding layer 215 may prevent the external light from being incident on the semiconductor layer 225. Furthermore, the light-shielding layer provided according to embodiments of the present disclosure may also prevent or reduce problems caused by charges that may flow from the substrate. For example, when a voltage is applied to a gate electrode of a thin film transistor for a long time, due to an electric field generated in the thin film transistor, charges of the substrate may flow into a channel region of a semiconductor pattern of the thin film transistor, thereby changing an amount of charge in the corresponding channel region. By providing the light-shielding layer between the substrate and the semiconductor layer to block or reduce undesired charges from flowing from the substrate into the thin film transistor, a change in a threshold voltage (Vth) of the thin film transistor may be prevented or reduced. The light-shielding layer may be formed of a metal material or a non-metal material. For example, the light-shielding layer 215 may be formed as a single layer or a multilayer made of any one of molybdenum (Mo), copper (Cu), titanium (Ti), aluminum (Al), chromium (Cr), gold (Au), nickel (Ni), neodymium (Nd), and tungsten (W), or an alloy thereof.

A gate insulating layer 230 may be disposed between the semiconductor layer 225 and the gate electrode 235. The gate insulating layer 230 may cover the semiconductor layer 225. The gate insulating layer 230 may be embodied as a single layer or a plurality of layers made of silicon oxide (SiOx) or silicon nitride (SiNx). The gate insulating layer 230 may extend into the non-display area NDA. A combination of the first buffer layer 210, the second buffer layer 220, and the gate insulating layer 230 extending into the non-display area NDA may be referred to as a first insulating structure 211.

The gate electrode 235 may be disposed on the gate insulating layer 230. The gate electrode 235 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the material thereof is not limited thereto.

The first intermediate electrode layer 236 may be disposed on the gate insulating layer 230. The first intermediate electrode layer 236 may be disposed in a different area from the area where the gate electrode 235 is disposed. The first intermediate electrode layer 236 may be made of the same material as that of the gate electrode 235 and be formed in the same process as the process of forming the gate electrode 235. The first intermediate electrode layer 236 may act as one of signal lines for transmitting various signals. In an example, the first intermediate electrode layer 236 may extend from the display area DA through the bezel area BZA1 and BZA2 to the pad area PDA. For example, an area where the first intermediate electrode layer 236 is disposed may be an area where the driving circuit chip DIC (see FIG. 2) is disposed.

A via hole extending through the gate insulating layer 230 and the second buffer layer 220 may be disposed. The via hole may expose a portion of the surface of the light shielding layer 215. A via electrode 223 may be disposed in the via hole. The via electrode 223 may contact and be connected to the portion of the light shielding layer 215 exposed through the via hole. The via electrode 223 may extend from the inside of the via hole to a portion of an upper surface of the gate insulating layer 230.

A first interlayer insulating layer 237 may be disposed on the gate electrode 235 and the first intermediate electrode layer 236. The first interlayer insulating layer 237 may be embodied as a single layer or multiple layers made of an inorganic insulating material such as silicon oxide (SiOx) or silicon nitride (SiNx).

A second intermediate electrode layer 238 may be disposed on the first interlayer insulating layer 237. The second intermediate electrode layer 238 may be disposed in a different area from an area in which the transistor TR is disposed. For example, the second intermediate electrode layer 238 may be disposed to overlap the first intermediate electrode layer 236 in the vertical direction with the first interlayer insulating layer 237 interposed therebetween.

The second intermediate electrode layer 238 may include a metal material. For example, the second intermediate electrode layer 238 may be embodied as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, the second intermediate electrode layer 238 may act as a plurality of lines that transmit various signals from the driving circuit chip DIC (see FIG. 2) or the driver disposed on the printed circuit board to the display area DA. For example, the various signals may include a high potential voltage, a low potential voltage, a scan signal, a data signal, a touch driving signal, or the like. However, embodiments of the present disclosure are not limited thereto. In an example, the second intermediate electrode layer 238 may extend from the display area DA through the bezel area BZA1 and BZA2 to the pad area PDA. For example, the area where the second intermediate electrode layer 238 is disposed may be an area where the driving circuit chip DIC (see FIG. 2) is disposed.

A second interlayer insulating layer 239 may be disposed on the second intermediate electrode layer 238 and the first interlayer insulating layer 237. The second interlayer insulating layer 239 may have a plurality of contact holes 243 formed therein. The plurality of contact holes 243 may extend through the second interlayer insulating layer 239, the first interlayer insulating layer 237, and the gate insulating layer 230 so as to contact portions of surfaces of the source/drain areas of the semiconductor layer 225, respectively. In some embodiments, a portion of the contact hole 243 may be disposed to overlap the via electrode 223 in the vertical direction. The second interlayer insulating layer 239 may be embodied as a single layer or multiple layers made of an inorganic insulating material such as silicon oxide (SiOx) or silicon nitride (SiNx).

The source/drain electrodes 245 may be disposed on the second interlayer insulating layer 239. The source/drain electrodes 245 may extend through the second interlayer insulating layer 239, the first interlayer insulating layer 237, and the gate insulating layer 230 to be connected to the source/drain areas of the semiconductor layer 225, respectively. One of the source/drain electrodes 245 may be connected to the via electrode 223 and thus be connected to the light shielding layer 215. Each of the source/drain electrodes 245 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, embodiments of the present disclosure are not limited thereto. In an example, each of the source/drain electrodes 245 may have a stacked structure of a titanium layer/aluminum layer/titanium layer (Ti/Al/Ti).

A planarization layer 250 may be disposed on the source/drain electrode 245 and the second interlayer insulating layer 239. The planarization layer 250 may planarize a step due to the pixel driving circuit thereunder. The planarization layer 250 may be formed in a structure in which a plurality of planarization layers are stacked in the vertical direction. For example, in the drawing, the planarization layer 250 has a structure in which a first planarization layer 251 and a second planarization layer 252 are stacked in the vertical direction. However, embodiment of the present disclosure are not limited thereto. For example, a multilayer structure in which a third planarization layer (not shown) is further stacked on the second planarization layer 252 may be included in embodiments of the present disclosure. For example, the planarization layer 250 may include an organic insulating material such as polyimide or acrylic resin.

The light-emitting element 285 may be formed on the planarization layer 250. For example, the light-emitting element 285 may be disposed on the second planarization layer 252. The light-emitting element 285 may include a first electrode 260, a light-emitting layer 270, a second electrode 275, and a capping layer 280.

The light-emitting element 285 may be electrically connected to the pixel driving circuit via the first electrode 260. For example, a pixel contact hole 255 may be formed in the planarization layer 250. The a pixel contact hole 255 may passing through the planarization layer 250, the second interlayer insulating layer 239, the first interlayer insulating layer 237, and the gate insulating layer 230. The pixel contact hole 255 may expose a portion of a surface of the other of the source/drain electrodes 245.

The first electrode 260 of the light-emitting element 285 may be electrically connected to the other of the source/drain electrodes 245 via the pixel contact hole 255. The first electrode 260 may be disposed on and contact the pixel contact hole 255 so as to be connected to the other of the source/drain electrodes 245 via the pixel contact hole 255.

The first electrode 260 may include a transparent conductive layer. The first electrode 260 may include ITO (Indium Tin Oxide) or IZO (Indium Zinc Oxide). Alternatively, the first electrode 260 may have a single-layer or multi-layer structure including a reflective metal film made of one of silver (Ag), aluminum (Al), gold (Au), nickel (Ni), and chromium (Cr) or an alloy thereof. The first electrode 260 may also be referred to as an anode electrode or a pixel electrode.

The bank 265 may be disposed on the first electrode 260. The bank 265 may be disposed to cover an edge of the first electrode 260. A portion of the bank 265 may extend onto the planarization layer 250. In an example, the bank 265 may fill a remaining portion of the trench other than the portion thereof filled with the pixel contact hole 255. The bank 265 may have the bank hole 265H defined therein as an opening exposing a portion of the upper surface of the first electrode 260. The portion of the upper surface of the first electrode 260 not covered with the bank 265 and exposed through the bank hole may be the light-emitting area EA. The bank 265 may be made of an organic insulating material. The bank 265 may include, for example, photosensitive polyimide, photoacryl, or benzocyclobutene (BCB). In an example, the bank 265 may include a black material, a light blocking material, or a light absorbing material. The bank 265 may include a material that absorbs light in a specific wavelength range. The bank 265 may have a structure in which at least two color filters of different colors among a red color filter, a green color filter, and a blue color filter are stacked.

The light-emitting layer 270 may be disposed on the first electrode 260. The light-emitting layer 270 may include a hole transport layer (HTL), an organic light-emitting layer (EML), an electron transport layer (ETL), a hole blocking layer (HBL), a hole injection layer (HIL), an electron blocking layer (EBL), and an electron injection layer (EIL). The light-emitting layer 270 may have a multi-stack structure in which two or more organic emission layers (EML) are stacked.

The second electrode 275 may be disposed on the light-emitting layer 270. The second electrode 275 may be formed over the entire surface of the substrate 205 so as to be commonly connected to the light-emitting layers 270 formed in all sub-pixels. Accordingly, the second electrode 275 may also be referred to as a cathode electrode or a common electrode. The second electrode 275 may include a transflective conductive material. For example, the second electrode 275 may include a metal material such as magnesium (Mg), silver (Ag), or an alloy (Ag-Mg) of silver (Ag) and magnesium (Mg). In an example, the second electrode 275 may include a transparent conductive layer made of, for example, indium-tin-oxide (ITO) or indium-zinc-oxide (IZO).

The capping layer 280 may be disposed on the second electrode 275. The capping layer 280 may correct optical characteristics by preventing light generated from the light-emitting layer 270 from being lost.

An encapsulation portion 290 may be disposed on the light-emitting element 285. The encapsulation portion 290 may protect the light-emitting element 285 from external oxygen or moisture. The encapsulation portion 290 may extend into the non-display area NDA while covering the display area DA.

The encapsulation portion 290 may include a multilayer structure in which a first encapsulation layer 291, a second encapsulation layer 292, and a third encapsulation layer 293 are stacked. The second encapsulation layer 292 may be disposed between the first encapsulation layer 291 and the third encapsulation layer 293.

The first encapsulation layer 291 may be disposed on the capping layer 280. The second encapsulation layer 292 may be disposed on the first encapsulation layer 291. The second encapsulation layer 292 may cover the first encapsulation layer 291 and may have a sufficient thickness so as to have a flat upper surface. The second encapsulation layer 292 may prevent foreign substances from invading into the light-emitting element 285. The third encapsulation layer 293 may be disposed on the second encapsulation layer 292.

An inorganic insulating material may be included in each of the first encapsulation layer 291 and the third encapsulation layer 293. For example, each of the first encapsulation layer 291 and the third encapsulation layer 293 may include at least one of silicon nitride (SiNx), silicon oxide (SiOx), and silicon oxynitride (SiON). An organic insulating material may be included in the second encapsulation layer 292. For example, the second encapsulation layer 292 may include at least one of epoxy, polyimide, polyethylene, and acrylate.

A touch sensing unit may be disposed on the encapsulation portion 290. A plurality of lenses 340 may be disposed on the touch sensing unit. The touch sensing unit may include a first touch buffer layer 295, a touch sensor 330, a second touch buffer layer 305, a light blocking pattern 310, a touch insulating layer 315, and a passivation layer 335.

The first touch buffer layer 295 may be disposed on the third encapsulation layer 293. The first touch buffer layer 295 may include an inorganic insulating material. For example, the first touch buffer layer 295 may include silicon nitride (SiNx). The first touch buffer layer 295 may relieve stress between the encapsulation portion 290 and the touch sensor 330.

The touch sensor 330 may include a plurality of touch electrodes 325 and a plurality of bridge electrodes 300. The plurality of touch electrodes 325 and the plurality of bridge electrodes 300 may be disposed in different layers. For example, the plurality of bridge electrodes 300 may be disposed on the first touch buffer layer 295. The plurality of touch electrodes 325 may be disposed on the touch insulating layer 315.

Each of the plurality of touch electrodes 325 or the plurality of bridge electrodes 300 may be embodied as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, each of the plurality of touch electrodes 325 or the plurality of bridge electrodes 300 may be a stacked structure of titanium layer/aluminum layer/titanium layer (Ti/Al/Ti).

The second touch buffer layer 305 may be disposed on the plurality of bridge electrodes 300 and the first touch buffer layer 295. The touch insulating layer 315 may be disposed between adjacent ones of the plurality of touch electrodes 325 and between adjacent ones of the plurality of bridge electrodes 300. The light blocking pattern 310 may be disposed on the second touch buffer layer 305. The plurality of touch electrodes 325 may be disposed on the touch insulating layer 315 so as to be spaced apart from each other. The bridge electrode 300 may electrically connect adjacent touch electrodes 325 to each other. To this end, each touch electrode 325 may extend through the touch insulating layer 315, the light blocking pattern 310, and the second touch buffer layer 305 so as to be electrically connected to the bridge electrode 300. Adjacent touch electrodes 325 may be electrically insulated from each other by the passivation layer 335.

An inorganic insulating material may be included in the second touch buffer layer 305 or the passivation layer 335. For example, the second touch buffer layer 305 or the passivation layer 335 may be made of an inorganic insulating material including silicon nitride (SiNx). In some embodiments, The first touch buffer layer 295 and the second touch buffer layer 305 may be disposed around the bridge electrode 300 such that an upper surface and a lower surface of the bridge electrode 300 may contact the first touch buffer layer 295 and the second touch buffer layer 305, respectively. In addition, the first touch buffer layer 295 and the second touch buffer layer 305 may further contact each other in an opening area 313 overlapping the light-emitting area EA.

The touch insulating layer 315 may spread or condense the light generated from the light-emitting element 285 such that the spread or condensed light is directed to the lens 340. To this end, the touch insulating layer 315 may be formed to have a sufficient thickness. It may be difficult to implement the inorganic insulating material layer as the touch insulating layer 315 so as to have a thickness required by the touch insulating layer 315. Accordingly, the touch insulating layer 315 may include an organic insulating material. For example, the touch insulating layer 315 may include an organic insulating material such as acryl resin, epoxy resin, phenolic resin, polyamide resin, or polyimide resin. However, the material thereof is not limited thereto.

The light blocking pattern 310 may be disposed on the second touch buffer layer 305. The light blocking pattern 310 may be disposed in an edge region of each light-emitting area EA, or disposed in a boundary of different light-emitting areas EA, and may be disconnected from each other in regions corresponding to the light emitting areas EA. In some embodiments, the light blocking pattern 310 may cover an upper surface and a side surface of the second touch buffer layer 305. The light blocking pattern 310 may prevent color mixing between light beams from adjacent light-emitting elements 285 from occurring. In addition, the light blocking pattern 310 may block light from the outside or may block light reflected from the outside. Accordingly, the luminance of the display apparatus may be further improved.

To this end, an opaque material may be included in the light blocking pattern 310. For example, the light blocking pattern 310 may include an organic insulating material including a black pigment or a black dye. In an example, the organic insulating material may include an organic material such as a benzocyclobutene resin, an epoxy resin, a polyimide resin, an acrylic resin, or a photosensitive polymer. However, embodiments of the present disclosure are not limited thereto.

A plurality of opening areas 313 may be disposed in the light blocking pattern 310. In an example, at least a portion of the opening area 313 may be disposed to overlap the light-emitting area EA of the light-emitting element 285. In an embodiment, one opening area 313 may overlap the light-emitting area EA of one sub-pixel SP. However, embodiments of the present disclosure are not limited thereto.

The plurality of lenses 340 may be disposed on the passivation layer 335. Adjacent lenses 340 may be arranged to be spaced apart from each other by a predetermined spacing. In an example, one lens 340 may be disposed to overlap one opening area 313 defined in the light blocking pattern 310. A width of one lens 340 may be equal to or greater than a width of one opening area 313. In other words, the lens 340 may completely cover an area of the opening area 313.

The lens 340 may be a hemispherical lens overlapping the opening area 313 in the vertical direction. For example, the lens 340 may have a hemispherical shape in which a convex surface protrudes toward the lens protection layer 350. A light-receiving surface of the lens 340 facing the protruding convex surface of the lens 340 receiving the light generated from the light-emitting element 285 may be a flat surface. The light-receiving surface of the lens 340 may be in contact with the passivation layer 335.

The light generated from the light-emitting element 285 and passing through the opening area 313 may be provided to the light-receiving surface of the lens 340 and refracted by the convex surface of the lens 340 to be emitted to the outside. The light beams emitted in various directions from the light-emitting element 285 may be subjected to the change in the travel path by the lens 340 so as to be condensed in the frontward direction. Accordingly, the viewing angle of the display apparatus may be controlled.

As shown in FIGS. 5 and 6, the lens 340 may include at least one of a first lens 340-1 or a second lens 340-2. The first lens 340-1 and the second lens 340-2 may have different shapes.

For example, referring to FIG. 5, the first lens 340-1 may have a rectangular bottom surface and may have a hemispherical cylindrical shape having a hemispherical side surface in a cross-sectional view. In the bottom surface of the rectangle of the first lens 340-1, light travel of the light emitted from a width area of one sub-pixel may not be limited in a first direction X-X′ (or row direction), while light travel of the light emitted from a length area of one sub-pixel may be limited in a second direction Y-Y′ (or column direction) as indicated by a mark “ⅹ”. Accordingly, the light traveling in the vertical direction may be limited, thereby controlling the viewing angle in the vertical direction.

In addition, referring to FIG. 6, the second lens 340-2 may have a circular bottom surface and may have a hemispherical shape. Thus, in the circular bottom surface of the second lens 340-2, light travel of the light emitted from a width area of one sub-pixel may be limited in a first direction X-X′ (or row direction) as indicated by a mark “ⅹ”, while light travel of the light emitted from a length area (or in other words, along a direction perpendicular to the previous width direction) of one sub-pixel may be limited in a second direction Y-Y′ (or column direction) as indicated by a mark “ⅹ”. When the display apparatus is disposed in the vehicle, the light travel along each of the vertical and horizonal directions may be limited such that the viewing angle in each of the vertical and horizontal directions of the display apparatus may be limited. Accordingly, when the second lens 340-2 is used in the display apparatus in front of the driver’s seat, the image therefrom can be individually recognized only by the driver on the driver’s seat. Further, when the second lens 340-2 is used in the display apparatus in front of the passenger’s seat, the image therefrom can be individually recognized only by the passenger on the passenger’s seat. For example, in some embodiments for practical applications, driving information need not be viewed by a passenger, while entertainment information or images are not suitable for a driver to pay attention to, thereby avoiding interference with the driver’s driving of the vehicle.

Referring to FIGS. 7 and 8, one or more display areas 10a and 10b may be disposed in the vehicle. The at least one display area 10a and 10b may include the first display area 10a and the second display area 10b. In addition, although not shown in the drawings, the third display area 10c (see FIG. 1) disposed in front of the passenger seat may be disposed.

Referring to FIG. 7, the viewing angle adjustment component may not be disposed in the display panel disposed in the second display area 10b positioned between the first display area 10a and the third display area 10c among the first to the third display areas 10a to 10c. In this case, an image IMG1 provided from the second display area 10b may reflect onto a first position 20a of the front glass 20 in the frontward and upward direction of the second display area 10b. The image IMG1 reflecting onto the first position 20a may interfere with the field of view of the user (or the driver). In contrast, as shown in FIG. 8, when the viewing angle adjustment component such as the lens as shown in FIGS. 5 and 6 is disposed in the display panel disposed in the second display area 10b, the light travel along the vertical and/or horizontal direction may be limited such that the viewing angle along the vertical and/or horizontal direction of the display panel disposed in the second display area 10b may be limited. Thus, the image IMG1 may not reflect onto the first position 20a. Accordingly, the field of view of the driver may be prevented from being interfered therewith when the driver is driving the vehicle.

Further making reference to FIG. 4 and FIG. 9, the lens protection layer 350 may be disposed on the lens 340. The polarization layer 360 may be disposed on the lens protection layer 350. The lens protective layer 350 may protect the lens 340 disposed thereunder from external foreign substances or the like. The lens protection layer 350 may be referred to as a lens protection member. In addition, the lens protection layer 350 may planarize a step generated by the lens 340. The lens protection layer 350 may extend from the display area DA into a partial area of the bezel area BZA1 and BZA2. In an example, the refractive index of the lens protection layer 350 may be lower than the refractive index of the lens 340. In sub-pixels of different colors (for example, red, green, and blue sub-pixels), the refractive index of the lens protection layer 350 may be lower than the refractive index of the lens corresponding to each color, respectively. Accordingly, light having passed through the lens 340 may be prevented from being directed toward the substrate 205.

An insulating material having fluidity may be included in the lens protection layer 350. The lens protection layer 350 may include the insulating material having fluidity and thus be formed in a shape having an upper flat surface in the display area DA. An organic insulating material may be included in the insulating material having fluidity. For example, the organic insulating material may include at least one of epoxy, polyimide, polyethylene, and acrylate. However, the material is not limited thereto.

When the insulating material having fluidity flows to the outer area (or edge area) of the display panel 10, a height of a portion of the lens protection layer 350 disposed in a portion of the display area DA closer to the bezel area BZA1 and BZA2 may be reduced. As a result, the height uniformity between the height of a portion of the lens protection layer 350 in the central area of the display area DA and the height of a portion of the lens protection layer 350 in the portion of the display area DA close to the bezel area BZA1 and BZA2 may be deteriorated. In other words, since a portion of the flowable material constituting the lens protection layer 350 inevitably flows toward the edge portions, the layer of the lens protection layer 350 in portions of the display area DA adjacent to the bezel regions BZA1 and BZA2 maBZA2come excessively thin, such that the lens protection layer 350 cannot be ensured to provide a satisfactory planarization function. If a partial region of the lens protection layer 350 becomes uneven, the edge region of the lens may also fail to be properly protected.

Accordingly, the display apparatus according to some embodiments of the present disclosure may include a structure for controlling the flow of the insulating material having fluidity in the bezel area. Hereinafter, this will be described with reference to the drawings.

FIGS. 9-11 are diagrams illustrating a display apparatus according to an embodiment of the present disclosure. FIG. 9 is a cross-sectional view taken along a line III-III′ of FIG. 2. FIG. 10 is an enlarged view of an area V of FIG. 9. FIG. 11 is a cross-sectional view taken along a line IV-IV′ of FIG. 2.

For example, FIG. 9 may show a cross-section of a partial area disposed in a lower portion of the display panel 10 (see FIG. 2), including a partial area of the display area DA, and the non-display area NDA. FIG. 11 may illustrate a cross-section of a partial area disposed in upper portion of the display panel 10 opposite to the lower portion, or in a left portion or right portion of the display panel 10, including a partial area of the display area DA and the non-display area NDA. In FIG. 10, the polarizing layer 360 is excluded for convenience of illustration. Since FIGS. 9-11 include the same components as those of FIG. 4, redundant descriptions thereof will be omitted or briefly set forth, and differences therebetween will be mainly described. Like reference numerals may denote like elements.

Referring to FIGS. 9-11, the first insulating structure 211 may be disposed on the substrate 205 and in the non-display area NDA. The first insulating structure 211 may include one or more insulating layers extending from the display area DA. For example, the first insulating structure 211 may include the first buffer layer 210, the second buffer layer 220, and the gate insulating layer 230. However, embodiments of the present disclosure are not limited thereto.

The first intermediate electrode layer 236 may be disposed on the first insulating structure 211 and in the non-display area NDA. In an example, the first intermediate electrode layer 236 may act as one of signal lines that transmit various signals. In the present disclosure, for convenience of description, an embodiment in which the first intermediate electrode layer 236 is made of the same material as that of the gate electrode 235 and be formed in the same process as the process for forming the gate electrode 235 will be described. In addition, in the present disclosure, for convenience of description, an embodiment in which the first intermediate electrode layer 236 is embodied as a single layer has been described. However, embodiments of the present disclosure are not limited thereto. For example, the first intermediate electrode layer 236 may be embodied as a stack of a plurality of layers.

The first interlayer insulating layer 237 may be disposed on the first intermediate electrode layer 236 and in the non-display area NDA. The first interlayer insulating layer 237 may include an inorganic insulating material and may extend from the display area DA. The second intermediate electrode layer 238 may be disposed on the first interlayer insulating layer 237 and in the non-display area NDA. The second intermediate electrode layer 238 may act as, for example, one of the signal lines for transmitting various signals. The second intermediate electrode layer 238 may extend into the pad area PDA.

The second interlayer insulating layer 239 may be disposed on the second intermediate electrode layer 238 and in the non-display area NDA. A signal line 245i may be disposed on the second interlayer insulating layer 239. The signal line 245i may be made of the same material as the material of the source/drain electrodes 245 and be formed in the same process as the process for forming the source/drain electrodes 245 (see FIG. 4). A pad electrode 245p made of the same material as that of the signal line 245i and be formed through the same process as the process for forming the signal line 245i may be disposed in the pad area PDA. The pad electrode 245p may be in contact with and electrically connected to the second intermediate electrode layer 238. Via the pad electrode 245p, various signals may be provided to the display area DA from the driving circuit chip or the driving unit disposed on the printed circuit board.

The planarization layer 250 may be disposed on the signal line 245i. The planarization layer 250 may be disposed in the display area DA and a portion of the bezel area BZA1 and BZA2. For example, a portion of the planarization layer 250 may act as a pad protection pattern 250p covering one side end of the pad electrode 245p. Here, the planarization layer 250 may cover a portion of an upper surface of the pad electrode 245p as well as a side surface thereof. The planarization layer 250 may also fill a gap between the signal lines 245i to sufficiently achieve planarization. The first electrode 260 extending from the display area DA may be disposed on the planarization layer 250 and in the non-display area NDA. The first electrode 260 may extend into a portion of the bezel area BZA1 and BZA2. The bank 265 may be disposed on the first electrode 260 and in the non-display area NDA. The bank 265 may extend into a portion of the bezel area BZA1 and BZA2.

A plurality of barrier patterns 267i, 265i, and 250b and a plurality of encapsulation dams 400 may be disposed in the bezel area BZA1 and BZA2, wherein in an exemplary embodiment, the plurality of encapsulation dams 400 may include a first encapsulation dam 410, a second encapsulation dam 420, and a third encapsulation dam 430.

The bezel area BZA1 and BZA2 may include a first bezel area BZA1 and a second bezel area BZA2. For example, as illustrated in FIG. 2, the first bezel area BZA1 may be positioned in a lower portion of the display panel 10. The second bezel area BZA2 may be positioned in an upper portion of the display panel 10 opposite to the lower portion, and in left and right portions of the display panel 10. For example, the pad area PDA in which a plurality of pad patterns are disposed may be positioned in the first bezel area BZA1.

The bezel area BZA1 and BZA2 may include a first area A1, a second area A2, and a third area A3. The first area A1 of the bezel area BZA1 and BZA2 may be an area closest to the display area DA among the first to third areas. The third area A3 of the bezel area BZA1 and BZA2 may be an area closest to an edge portion (or an end) of the substrate 205 among the first to third areas. For example, as illustrated in FIG. 9, the third area A3 of the first bezel area BZA1 may be an area adjacent to the pad area PDA. As illustrated in FIG. 11, the third area A3 of the second bezel area BZA2 maBZA2 an area closest to the end of the substrate 205 among the first to third areas. The second area A2 may be disposed between the first area A1 and the third area A3.

The plurality of barrier patterns 267i, 265i, and 250b and the plurality of encapsulation dams 400 may prevent the second encapsulation layer 292 including the organic insulating material from overflowing outwardly of the bezel area BZA1 and BZA2.

The plurality of barrier patterns 267i, 265i, and 250b may include a first barrier pattern 267i, a second barrier pattern 265i, and a third barrier pattern 250b. The first barrier pattern 267i may be positioned on the bank 265 and disposed in the first area A1 closest to the display area DA. The first barrier pattern 267i may be made of the same material as that of the spacer 267 and be formed through the same process as the process for forming the spacer 267 (see FIG. 4) of the display area DA. The encapsulation portion 290 covers upper surfaces and side surfaces of the plurality of barrier patterns 267i, 265i, and 250b such that the flow of the encapsulation portion is obstructed by the plurality of barrier patterns 267i, 265i, and 250b. In addition, the first barrier pattern 267i may be disposed on the bank 265 such that a height of the first barrier pattern 267i is greater than that of the second barrier pattern 265i and the third blocking pattern 250b.

The plurality of encapsulation dams 400 may include a first encapsulation dam 410, a second encapsulation dam 420, and a third encapsulation dam 430. The first encapsulation dam 410, the second encapsulation dam 420, and the third encapsulation dam 430 may be arranged to be spaced apart from each other by a predetermined spacing in a direction from the first area adjacent to the display area DA of the bezel area BZA1 and BZA2 to the end of the substrate 205. The plurality of encapsulation dams 400 may be disposed in the second area A2, or may be disposed in boundary regions between the first area A1, the second area A2, and the third area A3.

The first encapsulation dam 410 may be disposed in a boundary area between the first area A1 and the second area A2. The first encapsulation dam 410 may have a structure in which a first layer 265a as a lower layer and a second layer 267a as an upper layer are stacked. For example, the first layer 265a may be made of the same material as that of the bank 265 and be formed in the same process as the process for forming the bank 265. The second layer 267a may be made of the same material as that of the first barrier pattern 267i and be formed through the same process as the process for forming the first barrier pattern 267i. In an alternative embodiment, regardless of whether each encapsulation dam is formed as a single layer or multiple layers, a height of the first encapsulation dam 410 may be greater than a height of the second encapsulation dam 420, and a height of the third encapsulation dam 430 may be greater than the height of the second encapsulation dam 420.

The second barrier pattern 265i may be disposed in the first area A1. For example, the second barrier pattern 265i may be disposed between the first encapsulation dam 410 and the first barrier pattern 267i. The second barrier pattern 265i may be made of the same material as that of the bank 265 and be formed in the same process as the process for forming the bank 265. In an example, the second barrier pattern 265i may be disposed such that a plurality of patterns are spaced apart from each other.

The third encapsulation dam 430 may be disposed in a boundary area between the second area A2 and the third area A3 of the bezel area BZA1 and BZA2. The third encapsulation dam 430 may be spaced apart from the first encapsulation dam 410 while the third encapsulation dam 430 is disposed between the first encapsulation dam 410 and the end of the substrate 205. The third encapsulation dam 430 may have a structure in which a first layer 250a as a lower layer and a second layer 265c as an upper layer are stacked. For example, the first layer 250a of the third encapsulation dam 430 may be made of the same material as that of the planarization layer 250 and be formed in the same process as the process for forming the planarization layer 250. The second layer 265c of the third encapsulation dam 430 may be made of the same material as that of the bank 265 and be formed in the same process as the process for forming the bank 265.

The second encapsulation dam 420 may be disposed between the first encapsulation dam 410 and the third encapsulation dam 430. The second encapsulation dam 420 may include a plurality of patterns 265b1 and 265b2 spaced apart from each other in the horizontal direction. The plurality of patterns 265b1 and 265b2 may be made of the same material as that of the bank 265 and be formed in the same process as the process for forming the bank 265. The plurality of patterns 265b1 and 265b2 may include a first pattern 265b1 and a second pattern 265b2. However, embodiments of the present disclosure are not limited thereto, and at least three patterns may be included therein. Each of the first pattern 265b1 and the second pattern 265b2 may have a line shape extending along the periphery of the display area DA and surrounding the display area DA. In other words, since FIG. 9 illustrates a longitudinal cross-sectional view of the display area DA and the non-display area NDA of the display device, a cross section of each of the first pattern 265b1 and the second pattern 265b2 may have a rectangular or trapezoidal shape. However, in a plan view of the display apparatus, the first pattern 265b1 and the second pattern 265b2 may have annular line-shaped patterns. In this case, the second pattern 265b2 may be positioned outwardly of the first pattern 265b1, and the second pattern 265b2 may be positioned inwardly of the third encapsulation dam 430.

The third barrier pattern 250b may be disposed outwardly of the third encapsulation dam 430. For example, the third barrier pattern 250b may be disposed in the third area A3 as an edge area of the bezel area BZA1 and BZA2. The third barrier pattern 250b may be made of the same material as that of the planarization layer 250 and be formed through the same process as the process for forming the planarization layer 250. The third barrier pattern 250b may cover an end of the signal line 245i extending into the bezel area BZA1 and BZA2. The third barrier pattern 250b may have substantially the same height as the second encapsulation dam 420, and may have a height smaller than that of the first encapsulation dam 410 and the third encapsulation dam 430.

Each of the first encapsulation layer 291, the second encapsulation layer 292, and the third encapsulation layer 293 may extend from the display area DA into the bezel area BZA1 and BZA2. The first encapsulation layer 291 may cover the first barrier pattern 267i, the second barrier pattern 265i, the first encapsulation dam 410, the second encapsulation dam 420, and the third encapsulation dam 430. The third encapsulation layer 293 may be disposed on the second encapsulation layer 292 in the first area A1 of the bezel area BZA1 and BZA2, and may be in contact with the first encapsulation layer 291 in the second area A2 and the third area A3. An inorganic insulating material may be included in each of the first encapsulation layer 291 and the third encapsulation layer 293. The second encapsulation layer 292 may be disposed between the first encapsulation layer 291 and the third encapsulation layer 293.

The first touch buffer layer 295 may be disposed on the third encapsulation layer 293 and in the non-display area NDA. A plurality of bridge electrodes 300 may be disposed on the first touch buffer layer 295. Although not shown in the drawings, some of the plurality of bridge electrodes 300 may extend into the pad area PDA so as to be electrically connected to the pad electrode 245p.

The second touch buffer layer 305 may be disposed on the plurality of bridge electrodes 300. The second touch buffer layer 305 may extend into the bezel area BZA1 and BZA2 while covering the plurality of bridge electrodes 300. The second touch buffer layer 305 may extend along the shape of each of the first touch buffer layer 295 and the third encapsulation layer 293 disposed thereunder.

The touch insulating layer 315 may be disposed on the second touch buffer layer 305 and in the non-display area NDA. The touch insulating layer 315 may extend from the display area DA into the bezel area BZA1 and BZA2. A side end of the touch insulating layer 315 extending into the bezel area BZA1 and BZA2 may be implemented to have an inclined surface 315i having a slope. In addition, in the first bezel area BZA1, the side end of the touch insulating layer 315 may define a boundary area between the third area A 3 and the pad area PDA. In addition, in the second bezel area BZA 2, the side end of the touch insulating layer 315 may be positioned inwardly the side end of the substrate 205. For example, the side end of the touch insulating layer 315 may be positioned in the third area A3 of the bezel area BZA1 anBZA1A2.

The touch insulating layer 315 may have a sufficient thickness to planarize a step caused by the underlying structure. The touch insulating layer 315 may include an organic insulating material.

The plurality of touch electrodes 325 may be disposed on the touch insulating layer 315 and in the display area DA. The passivation layer 335 may be disposed on the touch electrode 325 and in the non-display area NDA. The passivation layer 335 may extend from the display area DA into the bezel area BZA1 and BZA2. The passivation layer 335 may be disposed on an upper surface of the touch insulating layer 315 made of an organic insulating material. The passivation layer 335 may extend into the third area A3 of the bezel area BZA1 and BZA2 so as to cover the inclined surface 315i of the side end of the touch insulating layer 315. The passivation layer 335 may be made of an inorganic insulating material to prevent moisture or foreign matter from invading into the touch insulating layer 315.

The lens 340 may be disposed on the passivation layer 335 and in the display area DA. The portion of the display area DA illustrated in FIGS. 9 and 11 may be an edge portion of the display area DA adjacent to the bezel area BZA1 and BZA2. Accordingly, the lens 340 disposed in the edge portion of the display area DA may act as a dummy pattern or lens.

The lens protection layer 350 may be disposed on the lens 340. The lens protection layer 350 may be formed by applying an insulating material having fluidity to planarize a step caused by the lens 340 or the like disposed thereunder. When there is no structure controlling the flow of the insulating material having the fluidity, the insulating material having the fluidity may spread into the outer area of the display panel due to the fluidity of the material. When the insulating material having fluidity flows to the area adjacent to the side end of the display panel 10, the overall height of the lens protection layer 350 may be reduced. As a result, the height uniformity of the lens protection layer 350 across the center portion to the edge portion of the display area DA may decrease. In the embodiments of the present disclosure, the term “structure” may refer to a component or element capable of controlling flowability of insulating material. The structure in the embodiments may include one or a combination of a barrier pattern, a spacer, an encapsulation dam, and a lens dam. For convenience of description and to distinguish structures located at different positions or having different compositions, various structures in the present disclosure may be referred to as a “first structure,” a “second structure,” and the like. However, the embodiments of the present disclosure are not limited thereto.

Accordingly, the structure for controlling the flow of the insulating material having fluidity may be disposed on the passivation layer 335 and in the bezel area BZA1 and BZA2. For example, the structure for controlling the flow of the insulating material having fluidity may be embodied as the plurality of lens dams 500. The plurality of lens dams 500 may include a first lens dam 510, a second lens dam 520, and a third lens dam 530. Adjacent ones of the lens dams 510, 520, and 530 may be arranged to be spaced apart from each other by a predetermined spacing. In an example, the plurality of lens dams 500 may have the same thickness. However, embodiments of the present disclosure are not limited thereto.

Each of the plurality of lens dams 500 may be made of the same material as that of the lens 340 and be formed in the same process as the process for forming the lens 340 of the display area DA. Accordingly, the display apparatus according to some embodiments of the present disclosure may reduce the number of the process steps, such that there is an effect that the production energy required for the production of the display apparatus may be reduced, thereby reducing the emission of greenhouse gas.

The plurality of lens dams 500 may be positioned in the bezel area BZA1 and BZA2. At least one of the plurality of lens dams 500 may be disposed in the second area A2 of the bezel area BZA1 and BZA2 in which the encapsulation dams 410, 420, and 430 are disposed.

Referring to FIG. 10, the first lens dam 510 may be disposed to overlap the first encapsulation dam 410 disposed in the second area A2 in the vertical direction. For example, a bottom surface of the first lens dam 510 may have a size of a first width 510w, and a bottom surface of the first encapsulation dam 410 may have a size of a second width 410w.

For example, the first width 510w of the first lens dam 510 may have a size in a range of 40 ㎛ to 55 ㎛. However, embodiments of the present disclosure are not limited thereto. A height of the first lens dam 510 may be smaller than the first width 510w. For example, a height of the first lens dam 510 may be in a range of 10 ㎛ to 15 ㎛. Each of the width and the height of each of the second lens dam 520 and the third lens dam 530 may be equal to each of the first width 510w and the height of the first lens dam 510. Accordingly, the width of the bottom surface of each of the lens dams 510, 520, and 530 may be greater than the height thereof. In this case, the contact area of the polarizing layer 360 to be described later in contact with each of the lens dams 510, 520, and 530 increases, the occurrence of the peel-off defect of the polarizing layer 360 may be prevented.

The first lens dam 510 may be a structure which first contacts the insulating material having fluidity spreading from the display area DA in the bezel area BZA1 and BZA2.

Therefore, it is preferable that an upper surface of the first lens dam 510 is positioned at a higher vertical level than a vertical level of an upper surface of each of the second and third lens dams 520 and 530. For example, when a portion of an upper surface of the first lens dam 510 corresponding to the largest thickness and a portion of an upper surface of the first encapsulation dams 410 disposed thereunder corresponding to the largest thickness overlap each other in the vertical direction, the upper surface of the first lens dam 510 may be positioned at a higher vertical level than a vertical level of an upper surface of each of the second and third lens dams 520 and 530. The height of the first lens dam 510 may be maintained at a size capable of controlling the flow of the flowable insulating material. As a result, the first lens dam 510 may first prevent the insulating material having fluidity from overflowing over the second lens dam 520 or the third lens dam 530. For example, the portion of the upper surface of the first lens dam 510 corresponding to the largest thickness may be a central portion thereof through which the first center line C1 of the first width 510w passes. In addition, the portion of the upper surface of the first encapsulation dam 410 corresponding to the greatest thickness may be a central portion thereof through which the second central line C2 of the second width 410w passes. Each of the first center line C1 and the second center line C2 may be a virtual line vertically passing through each of the first lens dam 510 and the first encapsulation dam 410.

Accordingly, the first center line C1 of the first width 510w of the first lens dam 510 may coincide with the second center line C2 of the second width 410w of the first encapsulation dam 410. Accordingly, the flow of the insulating material having fluidity may be controlled by the first lens dam 510 overlapping the first encapsulation dam 410 in the vertical direction and having the upper surface positioned at a higher vertical level than a vertical level of an upper surface of each of the second and third lens dams 520 and 530.

If the first lens dam 510 is disposed in the third area A3 that is positioned outwardly of the second area A2 in which the encapsulation dams 410, 420, and 430 are disposed, the insulating material having fluidity flows to the third area A3. Then, the uniformity between the thickness of the portion of the lens protection layer 350 in the central area of the display area DA and the thickness of the portion of the lens protection layer 350 in the edge portion of the display area DA close to the bezel area BZA1 and BZA2 may be deteriorated. Then, since the thickness of the lens protection layer 350 is not sufficiently secured in the edge area of the display area, there is a limitation in that a portion of the lens 340 in the edge area of the display area is not protected by the lens protection layer 350. In addition, if the lens dams 510, 520, and 530 are disposed in the third area A3, a limitation in which the insulating material having fluidity overflows may occur. Accordingly, it is preferable that at least one of the plurality of lens dams 500 is disposed in the second area A2 in which the encapsulation dams 410, 420, and 430 are disposed.

The second lens dam 520 may be disposed outwardly of the first lens dam 510.

The third lens dam 530 may be disposed outwardly of the second lens dam 520. The third lens dam 530 may include a first pattern portion 530a and a second pattern portion 530b. The first pattern portion 530a may have the same shape as that of the first lens dam 510 or the second lens dam 520. For example, the first pattern portion 530a may have a trapezoidal shape in the cross-sectional view. However, embodiments of the present disclosure are not limited thereto.

The second pattern portion 530b of the third lens dam 530 may be embodied as an extension pattern extending outwardly from one side surface of the first pattern portion 530a. The second pattern portion 530b may extend toward the edge portion (or the side end) of the substrate 205. For example, the second pattern portion 530b may extend along and on the inclined surface 315i of the touch insulating layer 315.

The second pattern portion 530b may cover the touch electrode (or a metal line) positioned on an edge area (or the end area) of the substrate 205 to prevent damage to the touch electrode from external impact, moisture penetration, or the like. This may prevent the occurrence of the touch operation failure due to damage to the touch electrode, thereby improving product reliability. The first pattern portion 530a and the second pattern portion 530b may be integrally formed with each other. The second pattern portion 530b may be formed in a halftone manner.

The polarization layer 360 may be disposed on the lens protection layer 350. The polarizing layer 360 may disposed across the display area DA, and the first area A1, the second area A2, and the third area A3 of the bezel area BZA1 and BZA2. The lens protection layer 350 may not be disposed beyond the first area A1 of the bezel area BZA1 and BZA2. In addition, the upper surface of the second pattern portion 530b disposed in the third area A3 may be positioned at a lower vertical level than a vertical level of the upper surface of the first pattern portion 530a. Accordingly, the upper surface of the display area DA and the upper surfaces of the first area A1 to the third area A3 of the bezel area BZA1 and BZA2 may be disposed at different vertical levels.

The plurality of lens dams 500 may be disposed between the first area A1 and the third area A3. For example, the plurality of lens dams 500 may be disposed in the second area A2. The polarizing layer 360 may continuously extend across the first area A1 to the third area A3 while being in contact with the plurality of lens dams 500 disposed in the second area A2. The polarizing layer 360 may be gradually included downwardly as the polarizing layer 360 from the first area A1 toward the third area A3. The polarizing layer 360 may be attached in close contact to the second pattern portion 530b of the third lens dam 530 disposed in the edge portion of the third area A3 and thus may not lift off. Accordingly, a defect in which the polarizing layer 360 lifts off due to a step may be prevented from occurring.

The display apparatus according to another embodiment of the present disclosure may reduce the occurrence of a defect in which the polarization layer 360 lifts off in the second area A2 of the bezel area BZA1 and BZA2 by modifying a shape of each of the plurality of lens dams 500. Hereinafter, this will be described with reference to the drawings.

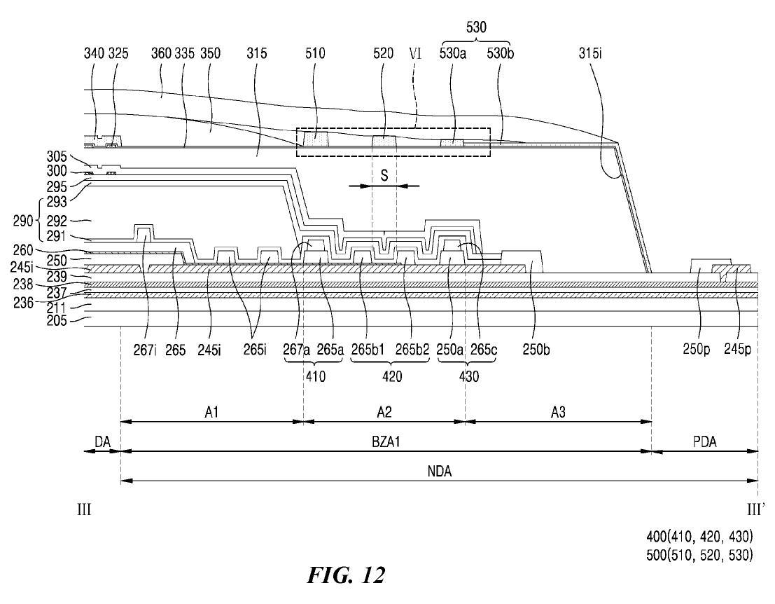

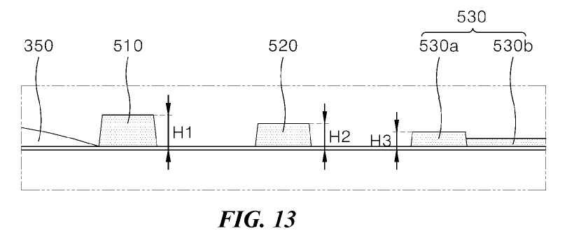

FIGS. 12 and 13 are diagrams illustrating a display apparatus according to another embodiment of the present disclosure. FIG. 12 is a cross-sectional view taken along a line III-III′ of FIG. 2. FIG. 13 is an enlarged view of an area VI of FIG. 12. Since FIGS. 12 and 13 include the same components as those of FIGS. 9 and 10 except for the lens dams, redundant descriptions thereof will be omitted or briefly set forth, and differences therebetween will be described. Like reference numerals may denote like elements.

Referring to FIGS. 12 and 13, the plurality of touch electrodes 325 may be disposed on the touch insulating layer 315 covering the underlying structures. The touch electrode 325 may be disposed in the display area DA. The passivation layer 335 may be disposed on the touch electrodes 325. The passivation layer 335 may extend from the display area DA into the third area A3 of the bezel area BZA1 and BZA2 so as to cover the inclined surface 315i of the touch insulating layer 315. The passivation layer 335 may include an inorganic insulating material.

The plurality of lens dams 500 may be disposed on the passivation layer 335. The plurality of lens dams 500 may include the first lens dam 510, the second lens dam 520, and the third lens dam 530. Each of the plurality of lens dams 500 may be made of the same material as that of the lens 340 of the display area DA and be formed in the same process as the process for forming the lens 340 of the display area DA.

The first lens dam 510, the second lens dam 520, and the third lens dam 530 may be arranged to be spaced apart from each other in the bezel area BZA1 and BZA2. At least one of the plurality of lens dams 500 may be disposed in the second area A2 of the bezel area BZA1 and BZA2 in which the encapsulation dams 410, 420, and 430 are disposed. For example, the first lens dam 510 may be disposed to overlap the first encapsulation dam 410 disposed in the second area A2 in the vertical direction. For example, as illustrated in FIG. 10, the first center line C1 of the first width 510w of the first lens dam 510 may coincide with the second center line C2 of the second width 410w of the first encapsulation dam 410 positioned thereunder.

The lens dams 510, 520, and 530 may have different heights H1, H2, and H3, respectively. Referring to FIG. 13, the first lens dam 510 may have a first height H1, the second lens dam 520 may have a second height H2, and the third lens dam 530 may have a third height H3.

The first lens dam 510 may be a structure which first contacts the insulating material having fluidity spreading from the display area DA in the bezel area BZA1 and BZA2. Therefore, it is preferable that the upper surface of the first lens dam 510 is positioned at a higher vertical level than a vertical level of each of the upper surface of each of the second and third lens dams 520 and 530 so as to control the flow of the insulating material having fluidity. Accordingly, the first height H1 of the first lens dam 510 may be the largest, and the third height H3 of the third lens dam 530 may be the smallest. The second height H2 of the second lens dam 520 may be smaller than the first height H1 and greater than the third height H3.

In an example, the third lens dam 530 may be disposed so as not to overlap the third encapsulation dam 430 disposed thereunder and in the second area A2 in the vertical direction. For example, in the plan view, the third lens dam 530 may be disposed outwardly of the third encapsulation dam 430 or at a position corresponding to or overlapping a position between the second pattern 265b2 of the second encapsulation dam 420 and the third encapsulation dam 430.

In another example, the third lens dam 530 may be disposed to overlap the third encapsulation dam 430 disposed thereunder and in the second area A2 in the vertical direction. In this case, the second lens dam 520 may be disposed at a position corresponding to or overlapping a space S between the first pattern 265b1 and the second pattern 265b2 of the second encapsulation dam 420. When the third lens dam 530 overlaps the third encapsulation dam 430 having the multi-layered structure in the vertical direction, the third height H3 of the third lens dam 530 may be relatively greater than the second height H2 of the second lens dam 520. Then, when the polarizing layer 360 is attached thereto, a physical pressure applied onto the third lens dam 530 having the relatively larger height than that of the second lens dam 520 may increase. When the physical pressure is continuously increased, the damage may occur to the third lens dam 530. When the damage occurs to the third lens dam 530, the second lens dam 520 may function to supplement the third lens dam 530, thereby maintaining the state in which the polarizing layer 360 is attached thereto. This may prevent the occurrence of the lift off defect of the polarizing layer 360 in the product.

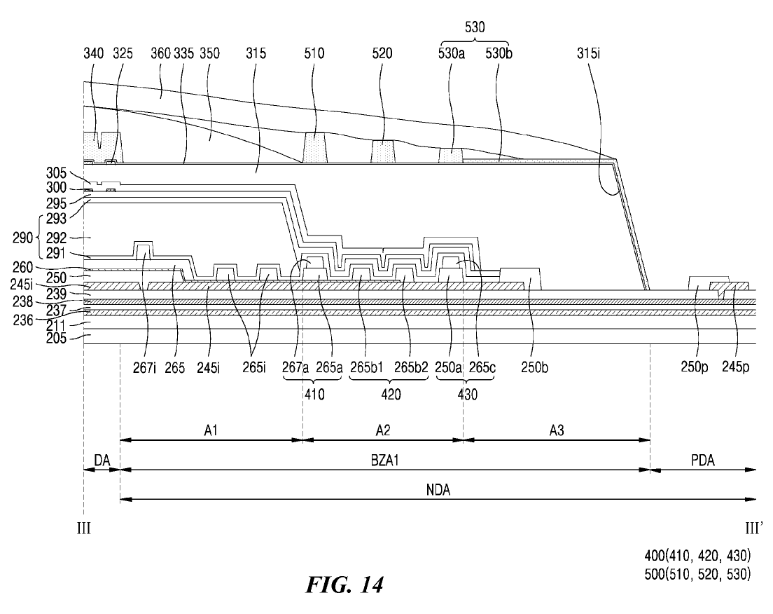

FIG. 14 is a diagram according to still another embodiment of the present disclosure. Since FIG. 14 includes the same components as those in FIG. 12 except for the lens dams, redundant descriptions thereof will be omitted or briefly set forth, and differences therebetween will be described. Like reference numerals may denote like elements.

Referring to FIG. 14, the plurality of lens dams 500 may be disposed on the passivation layer 335. The plurality of lens dams 500 may include the first lens dam 510, the second lens dam 520, and the third lens dam 530. Each of the plurality of lens dams 500 may be made of the same material as that of the lens 340 of the display area DA and be formed in the same process as the process for forming the lens 340 of the display area DA.

At least one of the plurality of lens dams 500 may be disposed in the second area A2 of the bezel area BZA1 and BZA2 in which the encapsulation dams 410, 420, and 430 are disposed. For example, the first lens dam 510 may be disposed to overlap the underlying first encapsulation dam 410 in the vertical direction. For example, as illustrated in FIG. 10, the first center line C1 of the first width 510w of the first lens dam 510 may coincide with the second center line C2 of the second width 410w of the first encapsulation dam 410 positioned thereunder.

The lens dams 510, 520, and 530 may be constructed to have different heights. For example, the height of the first lens dam 510 may be the largest. The height of each of the second lens dam 520 and the third lens dam 530 may be smaller than the height of the first lens dam 510.

The height of each of the lens dams 510, 520, and 530 according to another embodiment of the present disclosure may be greater than a width of the bottom surface thereof. The first lens dam 510, the second lens dam 520, and the third lens dam 530 may be arranged in a stepwise manner whose the vertical levels of the upper surfaces thereof are sequentially lowered as the first lens dam 510, the second lens dam 520, and the third lens dam 530 are sequentially arranged in a direction toward the side end of the substrate 205. The second lens dam 520 may be disposed between the first lens dam 510 and the third lens dam 530.

The polarizing layer 360 may continuously extend across the first area A1 to the third area A3 and be attached to the first area A1 to the third area A3. The polarizing layer 360 may be in contact with the lens dams 510, 520, and 530 arranged in the stepwise manner. Accordingly, the vertical level of the upper surface of the polarizing layer 360 may be gradually lowered as the polarizing layer 360 extends toward the third area A3. As a result, the polarizing layer 360 may be closely attached to the second pattern portion 530b of the third lens dam 530 disposed in the edge of the third area A3 and may not lift off.

The display apparatus according to various aspects and embodiments of the present disclosure may be described as follows.

A first aspect of the present disclosure provides a display apparatus comprising: a display area disposed on a substrate and including a plurality of light-emitting elements; a non-display area disposed outside the display area; and a bezel area located in the non-display area and including a second area in which a plurality of first structures are disposed, a first area between the second area and the display area, and a third area between the second area and an end portion of the substrate, an encapsulation portion, at least a portion of the encapsulation portion disposed on the plurality of first structures; a lens disposed above the encapsulation portion in the display area; a lens protection layer disposed on the lens, and a plurality of second structures disposed to be spaced apart from the lens, wherein at least one of the plurality of second structures is disposed in the second area of the bezel area in which the plurality of first structures are disposed.

In accordance with some embodiments of the first aspect, the display apparatus further comprises a touch sensing unit disposed on the encapsulation portion and including a touch sensor and a touch insulating layer; and the lens is disposed on the touch sensing unit.

In accordance with some embodiments of the first aspect, one second structure disposed in the second area overlaps one first structure of the plurality of first structures in a vertical direction, wherein the one first structure is disposed in a boundary area between the first area and the second area.

In accordance with some embodiments of the first aspect, a bottom surface of the one second structure has a first width, and a bottom surface of the one first structure has a second width, wherein a first center line vertically passing through a center of the first width of the one second structure and a second center line passing through a center of the second width of the one first structure coincide with each other.

In accordance with some embodiments of the first aspect, the plurality of first structures include: a first encapsulation dam disposed in the second area and in the boundary area between the first area and the second area; a third encapsulation dam disposed in the second area and in a boundary area between the second area and the third area; and a second encapsulation dam disposed in the second area and between the first encapsulation dam and the third encapsulation dam, wherein the first encapsulation dam is disposed to overlap one of the plurality of second structures in a vertical direction.

In accordance with some embodiments of the first aspect, the plurality of second structures includes: a first lens dam disposed in the second area so as to overlap one of the plurality of first structures in a vertical direction; a second lens dam disposed outwardly of the first lens dam; and a third lens dam disposed outwardly of the second lens dam.

In accordance with some embodiments of the first aspect, a bottom surface of the first lens dam has a first width, wherein a bottom surface of the one first structure overlapping the first lens dam in the vertical direction has a second width, wherein a first center line vertically passing through a center of the first width of the first lens dam and a second center line vertically passing through a center of the second width of the one first structure coincide with each other.

In accordance with some embodiments of the first aspect, the second structure and the lens are made of the same material and are formed in the same process.

In accordance with some embodiments of the first aspect, each of the first lens dam, the second lens dam, and the third lens dam each have a first width and a height smaller than the first width.

In accordance with some embodiments of the first aspect, an upper surface of the first lens dam is disposed at a position higher than an upper surface of the second lens dam or an upper surface of the third lens dam.

In accordance with some embodiments of the first aspect, the third lens dam includes a first pattern portion and a second pattern portion extending from one side surface of the first pattern portion outwardly.

In accordance with some embodiments of the first aspect, a height of an upper surface of the second pattern portion is lower than a height of an upper surface of the first pattern portion.

In accordance with some embodiments of the first aspect, an end portion of the touch insulating layer is positioned in the third area of the bezel area, wherein the second pattern portion of the third lens dam covers the end portion of the touch insulating layer.

In accordance with some embodiments of the first aspect, the first lens dam has a first height, the second lens dam has a second height, and the third lens dam has a third height, wherein the first height, the second height, and the third height are different from each other.

In accordance with some embodiments of the first aspect, the first height of the first lens dam is greater than each of the second height of the second lens dam and the third height of the third lens dam, wherein the second height of the second lens dam is greater than the third height of the third lens dam.

In accordance with some embodiments of the first aspect, the display apparatus further comprises a polarizing layer disposed on the plurality of second structures, wherein the polarizing layer extends from the display area toward the bezel area, and contacts an upper surface of each of the plurality of second structures.

In accordance with some embodiments of the first aspect, the first structure and the second structure include a component configured to control a flow of a flowable insulating material, and each of the first structure and the second structure includes one or more of a barrier pattern, a spacer, an encapsulation dam, and a lens dam.

A second aspect of the present disclosure provides a display apparatus comprising: a substrate including a display area and a non-display area outside the display area; a plurality of encapsulation dams disposed in the non-display area; an encapsulation portion disposed on the plurality of encapsulation dams; a touch sensing unit disposed on the encapsulation portion and including a touch sensor and a touch insulating layer; a lens disposed on the touch sensing unit; a lens protection layer disposed on the lens; and a plurality of lens dams disposed in the non-display area to be spaced apart from the lens, wherein one of the plurality of lens dams overlaps one of the encapsulation dams in a vertical direction.

In accordance with some embodiments of the second aspect, the plurality of encapsulation dams include a first encapsulation dam, a second encapsulation dam disposed outwardly of the first encapsulation dam, and a third encapsulation dam disposed outwardly of the second encapsulation dam, wherein the plurality of lens dams includes a first lens dam, a second lens dam disposed outwardly of the first lens dam, and a third lens dam disposed outwardly of the second lens dam, wherein the first lens dam is disposed to overlap the first encapsulation dam in the vertical direction.

In accordance with some embodiments of the second aspect, a bottom surface of the first lens dam has a first width, and a bottom surface of the first encapsulation dam has a second width, wherein a first center line vertically passing through a center of the first width of the first lens dam and a second center line vertically passing through a center of the second width of the first encapsulation dam coincide with each other.

In accordance with some embodiments of the second aspect, each of the first lens dam, the second lens dam, and the third lens dam each have a first width and a height smaller than the first width.

In accordance with some embodiments of the second aspect, the display apparatus further comprises a polarizing layer disposed on the plurality of lens dams, wherein the polarizing layer extends from the display area into the non-display area, and contacts an upper surface of each of the plurality of lens dams.

A third aspect of the present disclosure provides a display apparatus comprising: a display area disposed on a substrate and including a plurality of light-emitting elements; a non-display area disposed outside the display area; and a bezel area, the bezel area being located in the non-display area and including a first area adjacent to the display area, and a second area and a third area located farther from the display area than the first area; an encapsulation portion disposed in the first area and the second area; a lens disposed above the encapsulation portion; a lens protection member disposed on the lens; an insulating material flow control member disposed at the same height as the lens and spaced apart from the lens; and at least a portion of the lens protection member being located between the lens and the insulating material flow control member without extending beyond the insulating material flow control member.

In accordance with some embodiments of the third aspect, the insulating material flow control member includes one or more lens dams disposed apart from the lens, and the lens dams and the lens are disposed on a same insulating layer of the display apparatus.

In accordance with some embodiments of the third aspect, one or more encapsulation dams or barrier pattern protruding toward an interior of the encapsulation portion at a lower surface of the encapsulation portion, and at least a portion of the encapsulation dam overlaps the insulating material flow control member in the second area in a cross-sectional view of the display apparatus.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display area disposed on a substrate and including a plurality of light-emitting elements;
a non-display area disposed outside the display area; and
a bezel area located in the non-display area and including a second area in which a plurality of first structures are disposed, a first area between the second area and the display area, and a third area between the second area and an end portion of the substrate;
an encapsulation portion, at least a portion of the encapsulation portion being disposed on the plurality of first structures;
a lens disposed above the encapsulation portion;
a lens protection layer disposed on the lens; and
a plurality of second structures disposed to be spaced apart from the lens,
wherein at least one of the pluralities of second structures is disposed in the second area of the bezel area in which the plurality of first structures is disposed.

2. The display apparatus according to claim 1, wherein the display apparatus further comprises a touch sensing unit disposed on the encapsulation portion and including a touch sensor and a touch insulating layer; and
wherein the lens is disposed on the touch sensing unit.

3. The display apparatus of claim 1, wherein one second structure disposed in the second area overlaps one first structure of the plurality of first structures in a vertical direction, and
wherein the one first structure is disposed in a boundary area between the first area and the second area.

4. The display apparatus of claim 3, wherein a bottom surface of the one second structure has a first width, and a bottom surface of the one first structure has a second width, and
wherein a first center line vertically passing through a center of the first width of the one second structure and a second center line passing through a center of the second width of the one first structure coincide with each other.

5. The display apparatus of claim 1, wherein the plurality of first structures include:
a first encapsulation dam disposed in the second area and in a boundary area between the first area and the second area;
a third encapsulation dam disposed in the second area and in a boundary area between the second area and the third area; and
a second encapsulation dam disposed in the second area and between the first encapsulation dam and the third encapsulation dam,
wherein the first encapsulation dam is disposed to overlap one of the plurality of second structures in a vertical direction.

6. The display apparatus of claim 1, wherein the plurality of second structures includes:
a first lens dam disposed in the second area so as to overlap one of the plurality of first structures in a vertical direction;
a second lens dam disposed outwardly of the first lens dam; and
a third lens dam disposed outwardly of the second lens dam.

7. The display apparatus of claim 6, wherein a bottom surface of the first lens dam has a first width,
wherein a bottom surface of one first structure overlapping the first lens dam in the vertical direction has a second width, and
wherein a first center line vertically passing through a center of the first width of the first lens dam and a second center line vertically passing through a center of the second width of the one first structure coincide with each other.

8. The display apparatus of claim 1, wherein the plurality of second structures and the lens are made of the same material and are formed in the same process.

9. The display apparatus of claim 6, wherein each of the first lens dam, the second lens dam, and the third lens dam each have a first width and a height smaller than the first width.

10. The display apparatus of claim 6, wherein an upper surface of the first lens dam is disposed at a position higher than an upper surface of the second lens dam or an upper surface of the third lens dam.

11. The display apparatus of claim 6, wherein the third lens dam includes a first pattern portion and a second pattern portion extending from one side surface of the first pattern portion outwardly.

12. The display apparatus of claim 11, wherein a height of an upper surface of the second pattern portion is lower than a height of an upper surface of the first pattern portion.

13. The display apparatus of claim 11, wherein the display apparatus further comprises a touch sensing unit disposed on the encapsulation portion and including a touch sensor and a touch insulating layer, and an end portion of the touch insulating layer is positioned in the third area of the bezel area, and
wherein the second pattern portion of the third lens dam covers the end portion of the touch insulating layer.

14. The display apparatus of claim 6, wherein the first lens dam has a first height, the second lens dam has a second height, and the third lens dam has a third height,
wherein the first height, the second height, and the third height are different from each other.

15. The display apparatus of claim 14, wherein the first height of the first lens dam is greater than each of the second height of the second lens dam and the third height of the third lens dam,
wherein the second height of the second lens dam is greater than the third height of the third lens dam.

16. The display apparatus of claim 1, further comprising a polarizing layer disposed on the plurality of second structures, extending from the display area toward the bezel area, and contacting an upper surface of each of the plurality of second structures.

17. The display apparatus of claim 1, wherein the plurality of first structures and the plurality of second structures include a component configured to control a flow of a flowable insulating material, and each of the plurality of first structures and the plurality of second structures includes one or more of a barrier pattern, a spacer, an encapsulation dam, and a lens dam.

18. A display apparatus comprising:
a substrate including a display area and a non-display area outside the display area;
a plurality of encapsulation dams disposed in the non-display area;
an encapsulation portion, at least a portion of the encapsulation portion being disposed on the plurality of encapsulation dams;
a touch sensing unit disposed on the encapsulation portion and including a touch sensor and a touch insulating layer;
a lens disposed on the touch sensing unit;
a lens protection layer disposed on the lens; and
a plurality of lens dams disposed in the non-display area to be spaced apart from the lens,
wherein one of the plurality of lens dams overlaps one of the encapsulation dams in a vertical direction.

19. The display apparatus of claim 18, wherein the plurality of encapsulation dams include a first encapsulation dam, a second encapsulation dam disposed outwardly of the first encapsulation dam, and a third encapsulation dam disposed outwardly of the second encapsulation dam,
wherein the plurality of lens dams includes a first lens dam, a second lens dam disposed outwardly of the first lens dam, and a third lens dam disposed outwardly of the second lens dam, and
wherein the first lens dam is disposed to overlap the first encapsulation dam in the vertical direction.

20. The display apparatus of claim 19, wherein a bottom surface of the first lens dam has a first width, and a bottom surface of the first encapsulation dam has a second width, and
wherein a first center line passing through a center of the first width of the first lens dam and a second center line passing through a center of the second width of the first encapsulation dam coincide with each other.

21. The display apparatus of claim 19, wherein each of the first lens dam, the second lens dam, and the third lens dam each have a first width and a height smaller than the first width.

22. The display apparatus of claim 18, wherein the display apparatus further comprises a polarizing layer disposed on the plurality of lens dams, and
wherein the polarizing layer extends from the display area into the non-display area, and contacts an upper surface of each of the plurality of lens dams.

23. A display apparatus, comprising:
a display area disposed on a substrate and including a plurality of light-emitting elements;
a non-display area disposed outside the display area; and
a bezel area, the bezel area being located in the non-display area and including a first area adjacent to the display area, and a second area and a third area located farther from the display area than the first area;
an encapsulation portion disposed in the first area and the second area;
a lens disposed above the encapsulation portion;
a lens protection member disposed on the lens;
an insulating material flow control member disposed at the same height as the lens and spaced apart from the lens; and
at least a portion of the lens protection member being located between the lens and the insulating material flow control member without extending beyond the insulating material flow control member.

24. The display apparatus of claim 23, wherein the insulating material flow control member includes one or more lens dams disposed apart from the lens, and the lens dams and the lens are disposed on a same insulating layer of the display apparatus.

25. The display apparatus of claim 23, wherein one or more encapsulation dams or a barrier pattern protrude toward an interior of the encapsulation portion at a lower surface of the encapsulation portion, and at least a portion of one of the encapsulation dams overlaps the insulating material flow control member in the second area in a cross-sectional view of the display apparatus.
